(19) United States
(12) Patent Application Publication
(10) Pub. No.: US 2015/0241477 A1
(43) Pub. Date: Aug. 27, 2015

(54) EFFECTIVE AND EFFICIENT SOLUTION FOR PIN TO PAD CONTACTOR ON WIDE RANGE OF SMD PACKAGE TOLERANCES USING A REVERSE FUNNEL DESIGN ANVIL HANDLER MECHANISM

(71) Applicant: Texas Instruments Incorporated, Dallas, TX (US)

(72) Inventors: Mhark Lester L. Ponghon, Anupul (PH); Allan C. Castillo, Baguio City (PH)

(21) Appl. No.: 14/172,348

(22) Filed: Feb. 27, 2014

(51) Int. Cl. G01R 1/073; G01R 1/04

(52) U.S. Cl. CPC G01R 1/07364; G01R 1/0408

(57) ABSTRACT

The problem of poor device pad to contactor pin presentation because of wide range of package size tolerance limited by process capability is minimized by a reverse funnel anvil design.

### FIELD OF THE INVENTION

This invention relates to the field of test equipment for integrated circuits. More particularly, this invention relates the handler mechanism used for presentation of Leadless Surface Mount (SMD) integrated circuits to be tested to the test equipment.

### BACKGROUND OF THE INVENTION

Handler mechanisms on current test systems must handle a wide range of (SMD) device body tolerances of up to 0.2 mm, which can affect the contactor pin to device contact pad presentation causing incorrect package alignment on the device alignment plate. The misalignment can cause electrical failures especially on continuity testing. Moreover, the electrical failures reduce productivity due to additional manual rescreens required to confirm or reject the continuity failures from the first test sequence.

Many current handler mechanisms utilize a chuck FIG. 1, having a fixed opening on the chuck internal vertical wall 101 to align the device to be tested with contacts on the tester.

Taking into consideration a package size tolerance of 0.2 mm range or +/−0.1 mm, implementing a fixed opening dimension on the chuck/anvil vertical wall of a nominal package tolerance of +0.1 mm will have a problem of device movement against the chuck especially if devices are on the lower side of the tolerance. Tightening the fixed opening dimension on the vertical chuck wall 101 to target devices that are on lower side of the tolerance will induce stuck devices on the chuck especially if device is on the high side of the tolerance. Making the chuck cavity large enough to tolerate package on the high side of the tolerance can cause high continuity failures while reducing the chuck cavity size to tolerate the packages on the low side of the tolerance will reduce continuity failures but will generate more test problems by increasing jamming problems with the handler mechanism.

An obvious approach is to control the device body package tolerance. However, assembly yields suffer and cost increases due to increase scrappage of device not meeting the tighter tolerance.

As mentioned above, another approach is adjust the pocket opening of the existing vertical wall anvil 101 to capture devices that are on the lower side of the tolerance. However, devices can become stuck in the chuck for devices that fall on the higher side of the tolerance.

As such, there has arisen a need for a method of providing better device pad to contactor pin presentation for a wide range of package tolerance. A device chuck that will provide better device pad to contactor pin presentation for a wide range of package tolerance is needed.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In accordance with an embodiment of the present application, a test system contactor chuck is provided. The test system contactor chuck comprises: A test system handler head comprising: a chuck, having a bottom end with rectangular sides; an anvil formed in the bottom end of the chuck, wherein the anvil has a rectangular surface topology which includes a rectangular recess in the bottom end of the chuck; wherein the sides of the rectangular recess are inside and spaced apart from the rectangular sides of the bottom of the chuck; the rectangular recess having a top and a bottom, wherein the top of the recess is coplanar with the bottom of the chuck and the bottom of the recess is parallel and a distance “C” from the top of the recess, also wherein the sides of the recess are slanted away from the sides of the chuck; the dimension of the rectangle “A” at the bottom of the recess is equal to the minimum tolerance size of the device to be contacted, the dimension of a rectangle “B” at the top of the recess is equal to the maximum size of the device to be contacted and the distance from the top the recess to the bottom of the recess dimension “C” is less than the maximum thickness of the device to be contacted but large enough to provided sufficient contact for alignment of the device with the chuck, thus allowing the device to protrude from the bottom of the chuck; an alignment plate, wherein the alignment plate pre-aligns the device for presentation to the chuck; and a vacuum pad for securing the device to the chuck during test.

In accordance with another embodiment of the present invention, A method of operating a test system chuck comprising: providing a chuck, with an recess formed in the bottom end of the chuck; wherein the dimension of bottom of the recess is equal to the minimum tolerance size of the device to be contacted, the dimension the top of the recess is equal to the maximum size of the device to be contacted and the distance from the top the recess to the bottom of the recess is less than the maximum thickness of the device to be contacted but large enough to provided sufficient contact for alignment of the device with the chuck, thus allowing the device to protrude from the bottom of the chuck; moving the a device to be tested closer to the chuck until they touch one another, wherein the recess in the chuck positions the device first correctly within its walls before vacuum pad initiates the action of picking it up, wherein Aligning the device with the chuck before vacuum pick-up, allows for better device alignment on the chuck as it ensures devices to be always at the center of the chuck regardless if it the device package dimension is at the minimum or maximum of the package tolerance; and proceeding to test the device.

### DESCRIPTION OF THE VIEWS OF THE DRAWING

The following detailed description will be more readily understood in conjunction with the accompanying drawings, in which:

FIG. 1 is a sectional view of an exemplary test chuck having a vertical wall anvil, with a surface mount device aligned therein, according to one embodiment of this invention.

FIG. 2 is a sectional view of an exemplary test chuck having a reverse funnel anvil, with surface mount a device aligned therein, according to one embodiment of this invention.

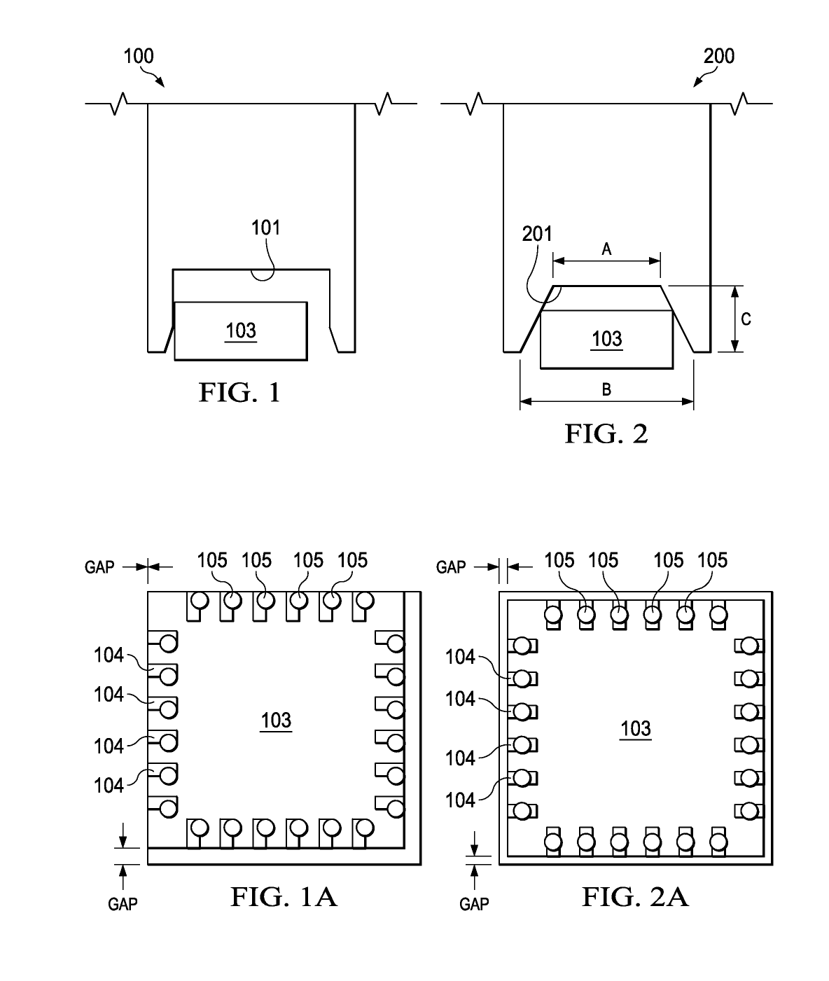

FIG. 1A is a bottom view of a surface mount device contained in a test chuck, having a vertical wall anvil, detailing alignment gaps and test probe locations, according to one embodiment of this invention.

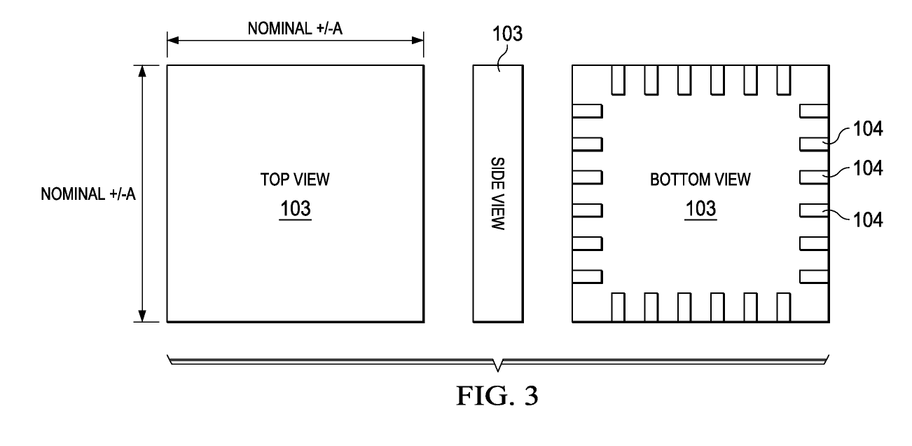

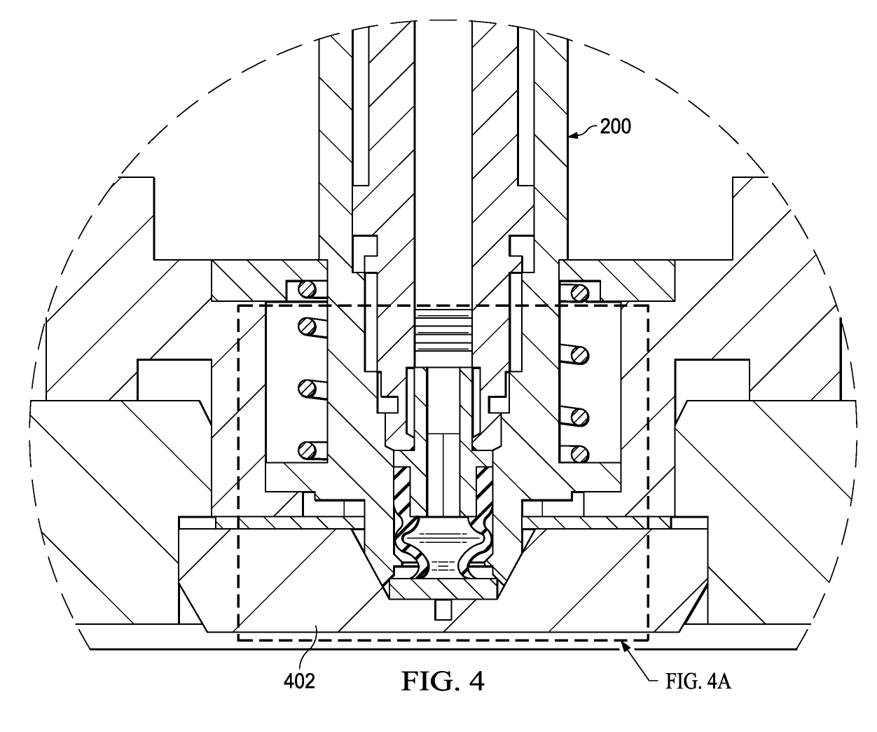

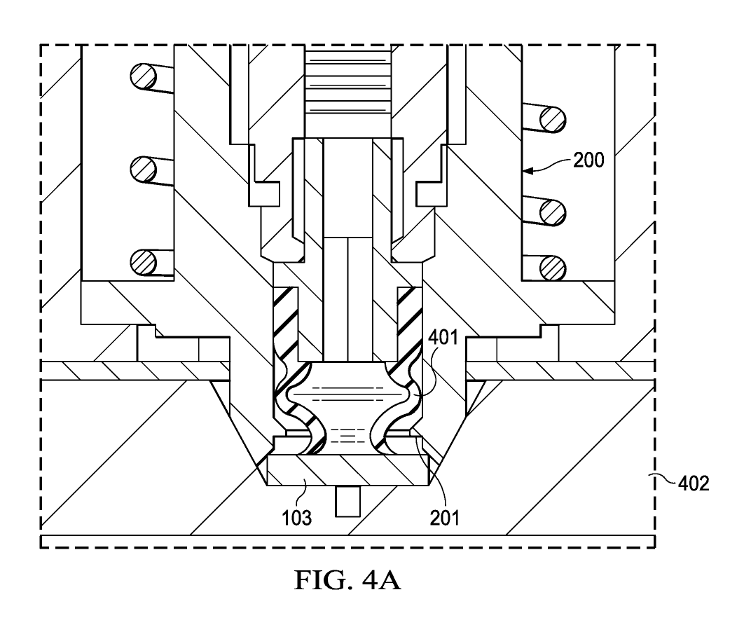

FIG. 2A is a bottom view of a surface mount device contained in a test chuck, having a reverse funnel anvil, detailing alignment gaps and test probe locations, according to one embodiment of this invention.

FIG. 3 is a front, back and side view of an exemplary surface mount device.

FIG. 4 is a side view of an exemplary test head detailing the test chuck, the device alignment plate and associated hardware, according to one embodiment of this invention.

FIG. 4A is an enlarged view of the test chuck and alignment plate, according to one embodiment of this invention.

In the drawings, like reference numerals are sometimes used to designate like structural elements. It should also be appreciated that the depictions in the figures are diagrammatic and not to scale.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

The solution to the problems associated with a vertical anvil wall is to provide a funnel anvil 201 FIG. 2 instead of vertical anvil 101 FIG. 1. The funnel anvil 201 configuration allows device to be always at the center of the chuck 200. Moreover, it tolerates devices with measurements within the package tolerance.

FIG. 1 shows an example of a vertical anvil chuck 100 designed to the nominal size of the subject surface mount device 103. The figure shows a device 103 at the minimum tolerance. It can be easily recognized that the device 103 can slide sideways in the anvil cavity 101 producing test probe 105 misalignment as shown in the bottom view of the device and chuck 200 in FIG. 1A

In order to have good alignment between the contactor pins 105 and device contact pads 104 even under the 0.2 mm device body tolerance range is to make sure that device is always at the center of the chuck. This invention ensures that the device is always at the center of the chuck before presenting it to the contactor, regardless of how the device body dimension plays within the existing package tolerance. Not only does the funnel anvil 201 align the devices in the center of the chuck 200, but it also insures that all devices within the tolerances of the package size will be centered by the chuck 200 and also provide that no device movement (if device is smaller than nominal) and no stuck device (if device is larger than the nominal). The funnel shaped anvil 201 allows device 103 to be always at the center of the chuck as is obvious from the bottom view of the chuck and device in FIG. 2A. Moreover, it tolerates a device with measurements within the package tolerance range.

Current practice in the industry is for the chuck to have a clearance against the top of the device package. In addition, the vacuum pad 401 in FIG. 4A touches the device first before the anvil. However, allowing the vacuum pad 401 to touch the device first restricts the device from self aligning on the anvil and forcing the device to move along with the vacuum pad 401 movement and location. This reduces the optimum alignment capability offered by the reverse funnel anvil 201 on the chuck as well as other existing vertical anvil wall 100 hardware. The solution is to move the device closer to the chuck until they touch one another. At worst case where device becomes thicker and device & chuck overlaps with each other, a spring is embedded in the chuck mechanism that will absorb any excess impact to prevent the device from breaking Using the aforementioned method, the anvil positions the device first correctly within its walls before vacuum pad initiates the action of picking it up.

In practice, the reverse funnel wall cavity 201, FIG. 2 is configured such that the dimension A at the top of the funnel is equal to the minimum tolerance size of the device to be contacted. The dimension B at the bottom of the funnel is equal to the maximum size of the device to be contacted and the dimension C is less than the maximum thickness of the device to be contacted but large enough to provided sufficient contact for alignment of the device with the chuck, thus allowing the device to protrude from the bottom of the chuck. For a nominal 3×3 mm device with a 1 mm thickness the dimensions would be A=2.90, B=3.10 and C=0.33 mm.

Aligning the device with the chuck before vacuum pick-up, allows for better device alignment on the chuck as it ensures devices to be always at the center of the chuck regardless if it the device package dimension is at the minimum or maximum of the package tolerance.

As can be seen by comparing FIGS. 1A and 2A, better device pad 104 to contactor pin 105 presentation can be obtained with the reverse funnel anvil, because the device is always at the center of the hardware, thus minimizing continuity problems.

There is no device sticking or device shifting or rotation since reverse the funnel comprehends the 0.2 mm or more package tolerance.

FIG. 4 is a side view of an exemplary test head detailing the test chuck 200, the device alignment plate 402 and associated hardware, according to one embodiment of this invention.

FIG. 4A is an enlarged view of the test chuck 200, the alignment plate 402, the anvil 201, the vacuum pad 401 and the device 103 to be tested, according to one embodiment of this invention.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A test system handler head comprising:
a chuck, having a bottom end with rectangular sides;
an anvil formed in the bottom end of the chuck, wherein the anvil has a rectangular surface topology which includes a rectangular recess in the bottom end of the chuck;
wherein the sides of the rectangular recess are inside and spaced apart from the rectangular sides of the bottom of the chuck;
the rectangular recess having a top and a bottom, wherein the top of the recess is coplanar with the bottom of the chuck and the bottom of the recess is parallel and a distance “C” from the top of the recess, also wherein the sides of the recess are slanted away from the sides of the chuck;
the dimension of the rectangle “A” at the bottom of the recess is equal to the minimum tolerance size of the device to be contacted, the dimension of a rectangle “B” at the top of the recess is equal to the maximum size of the device to be contacted and the distance from the top the recess to the bottom of the recess dimension “C” is less than the maximum thickness of the device to be contacted but large enough to provided sufficient contact for alignment of the device with the chuck, thus allowing the device to protrude from the bottom of the chuck;
an alignment plate, wherein the alignment plate pre-aligns the device for presentation to the chuck; and
a vacuum pad for securing the device to the chuck during test.

2. The test system handler head of claim 1, wherein the A, B and C dimensions for a nominal 3×3 mm device with a 1 mm thickness are A=2.90, B=3.10 and C=0.33 mm.

3. A method of operating a test system chuck comprising:
providing a chuck, with an recess formed in the bottom end of the chuck;
wherein the dimension of bottom of the recess is equal to the minimum tolerance size of the device to be contacted, the dimension the top of the recess is equal to the maximum size of the device to be contacted and the distance from the top the recess to the bottom of the recess is less than the maximum thickness of the device to be contacted but large enough to provided sufficient contact for alignment of the device with the chuck, thus allowing the device to protrude from the bottom of the chuck;
moving the a device to be tested closer to the chuck until they touch one another, wherein the recess in the chuck positions the device first correctly within its walls before vacuum pad initiates the action of picking it up, wherein Aligning the device with the chuck before vacuum pick-up, allows for better device alignment on the chuck as it ensures devices to be always at the center of the chuck regardless if it the device package dimension is at the minimum or maximum of the package tolerance; and
proceed to test the device.
